(19) United States
(12) Patent Application Publication
(10) Pub. No.: US 2012/0049049 A1
(43) Pub. Date: Mar. 1, 2012

(54) SHOCK-MOUNTED IMAGING MODULE WITH INTEGRATED WINDOW FOR RESISTING BACK REFLECTIONS IN AN IMAGING READER

(75) Inventors: Igor VINOGRADOV, Oakdale, NY (US); Edmond L. FRATIANNI, Port Jefferson Station, NY (US)

(73) Assignee: SYMBOL TECHNOLOGIES, INC., Holtsville, NY (US)

(21) Appl. No.: 12/871,158

(22) Filed: Aug. 30, 2010

(51) Int. Cl. H01L 31/0232; G06K 7/14

(52) U.S. Cl. 250/216

(57) ABSTRACT

An imaging module for an imaging reader for electro-optically reading a target by image capture, includes a chassis bounding an optical compartment, an illuminating light assembly in the compartment for illuminating the target with illumination light for return from the target, an image capture assembly in the compartment for capturing return light from the target over a field of view, and a light-transmissive window for the reader. The window is supported by, and integrated with, the chassis for joint movement therewith. The window is preferably positioned in a close confronting relationship with the illuminating light assembly to resist back reflections of the illumination light from the window from entering the field of view of the image capture assembly. The integrated imaging module is shock mounted in the reader to damp shock forces.

### DESCRIPTION OF THE RELATED ART

Solid-state imaging systems or imaging readers have been used, in both handheld and/or hands-free modes of operation, to electro-optically read targets to be decoded, such as one-dimensional bar code symbols, particularly of the Universal Product Code (UPC) symbology having a row of bars and spaces spaced apart along a scan direction, as well as two-dimensional symbols, such as the Code 49 symbology having a plurality of vertically stacked rows of bar and space patterns in a single symbol, as described in U.S. Pat. No. 4,794,239, and even non-symbol targets to be imaged, such as documents.

The known imaging reader includes a housing either held by an operator and/or supported on a support surface, a window supported by the housing and aimed at the target during reading, and an imaging engine or module supported by the housing and spaced away from the window. The imaging module has a chassis bounding an optical compartment in which are accommodated a solid-state imager with a sensor array of photocells or light sensors that correspond to image elements or pixels in a field of view of the imager, and an imaging lens assembly for capturing return light scattered and/or reflected from the target being imaged along an imaging axis through the window, and for projecting the return light onto the sensor array to initiate capture of an image of the target. Such an imager may include a one- or two-dimensional charge coupled device (CCD) or a complementary metal oxide semiconductor (CMOS) device and associated circuits for producing and processing electrical signals corresponding to a one- or two-dimensional array of pixel data over the field of view. These electrical signals are decoded by a programmed microprocessor or controller into data indicative of the symbol being read, or into a picture of the target.

It is therefore known to use the imager for capturing a monochrome image of a target or symbol as, for example, disclosed in U.S. Pat. No. 5,703,349. It is also known to use the imager with multiple buried channels for capturing a full color image of the symbol as, for example, disclosed in U.S. Pat. No. 4,613,895. It is common to provide a two-dimensional CCD with a 640×480 resolution commonly found in VGA monitors, although other resolution sizes are possible.

In order to increase the amount of the return light captured by the sensor array, especially in dimly lit environments and/or at far range reading, the optical compartment of the known imaging module may also accommodate an illuminating light assembly for illuminating the target with illumination light from an illuminating light source, e.g., one or more light emitting diodes (LEDs) and illuminating lenses, through the window for reflection and scattering from the target. Sometimes, an aiming light assembly is also provided in the optical compartment for projecting an aiming light pattern or mark with aiming light from an aiming light source, e.g., an aiming laser or one or more LEDs, through aiming lenses and through the window, on the target prior to imaging.

Although the known imaging reader is generally satisfactory for its intended purpose, one problem associated with spacing the housing window away from the imaging module relates to back reflections of the illumination light emitted by the illuminating light source, or from any other interior light source, off the window and inwardly back toward the imaging lens assembly. These back reflections into the field of view of the imager may create hot spots or stray light in the captured target image. Any dust and like contaminants that are deposited on the window, and/or any imperfections in the window itself, are substantially highlighted by the illumination light, thereby degrading reading performance and limiting image capture quality.

To minimize such back reflections, the prior art has proposed tilting the window at a substantial angle relative to the imaging axis so that the back reflections are directed away from the field of view of the imager. This approach, however, increases the overall size of the imaging reader and, in any event, does not solve the window imperfection problem. The prior art has also proposed disabling the illumination light during image capture, but acceptable levels of ambient light are not always available.

Still another prior art approach to minimize back reflections is to position the window substantially perpendicular to the imaging axis and as close as possible to the imaging lens assembly so that the back reflections do not enter the field of view of the imager. This approach, however, can cause the window to crack and break when the reader is subjected to shock forces. For example, if the reader is dropped, or even roughly handled, the imaging module will move relative to the window. If the window is physically close to the imaging module and in its path of travel, then the window can be scratched, or even crack and break. Hence, a relatively large spacing is needed in the prior art readers between the window and the imaging module to prevent such damage. However, any such large spacing aggravates the above-described back reflection problem.

Accordingly, it would be desirable to protect the window from scratching, cracking and breakage, as well as to minimize such back reflections in an imaging reader.

### SUMMARY OF THE INVENTION

The present invention relates to an imaging reader for electro-optically reading a target by image capture. The reader includes a housing, a light-transmissive window, and an imaging engine or module mounted in the housing for capturing return light from the target through the window along an imaging axis. The imaging module includes a chassis having chassis walls bounding an optical compartment in which a solid-state imager with a sensor array of photocells or light sensors, e.g., a CCD or CMOS device, and an imaging lens assembly, are both mounted. The imaging module also includes an illuminating light assembly for illuminating the target through the window with illumination light from an illuminating light source, e.g., one or more light emitting diodes (LEDs) and illuminating lenses, for reflection and scattering from the target, and an aiming light assembly for projecting an aiming light pattern or mark through the window with aiming light from an aiming light source, e.g., an aiming laser or one or more LEDs, through aiming lenses on the target prior to imaging.

In accordance with one aspect of this invention, the window for the reader is not directly supported by the housing, but instead, is supported by, and integrated with, the chassis walls for joint movement with the chassis. The window is positioned on the chassis, preferably in a close confronting relationship with the illuminating light assembly, to resist back reflections of the illumination light from the window from entering the field of view of the image capture assembly. The window is made of glass, plastic or like material transmissive to the illumination light, the aiming light and ambient light. The window may have a hard coating thereon to improve its scratch-resistant properties. In a preferred embodiment, the window is generally flat. However, other shapes, such as cylindrical, spherical, aspherical, toroidal, and the like may be utilized. The window may advantageously be formed with local curvatures for modifying the optical properties of the imaging lens assembly, the illuminating light assembly, or the aiming light assembly.

Preferably, a seal is provided between the window and the chassis walls for sealing the optical compartment from moisture, contaminations and stray light. A shock mount is operative for shock mounting the imaging module, together with its integrated window, in the housing to damp and resist any shock forces.

Hence, by positioning the window substantially perpendicular to the imaging axis and as close as possible to the imaging lens assembly and to the illuminating light assembly, any back reflections are minimized, because any such back reflections do not enter the field of view of the imager. A relatively large spacing between the window and the imaging module is no longer needed to prevent scratching, cracking and breakage of the window when the reader is subjected to shock forces. The window is thus protected from such damage, and such back reflections are minimized.

Another feature of the present invention is that the imaging module with its integrated window can be easily installed in original equipment manufacturer (OEM) product applications. Product integrators of the imaging module do not need to be concerned with correctly locating the exit window in the final product, since the window is already provided with the imaging module. The imaging module with its integrated window comprise an air/moisture sealed unit and, by this means, further facilitates its easy integration of the sealed unit in OEM products.

Still another feature of the present invention resides in a method of resisting and avoiding back reflections of illumination light from a window from entering a field of view of an image capture assembly in an imaging reader for capturing return light from a target to be electro-optically read. The method is performed by supporting the window by a chassis for joint movement with the chassis to form an integrated imaging module, and by positioning the window in close confronting relationship with an illuminating light assembly that illuminates the target through the window with the illumination light to resist the back reflections from entering the field of view of the image capture assembly. The integrated imaging module is advantageously protected from shock forces by a surrounding collar that is mounted in the reader.

The novel features which are considered as characteristic of the invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 is a perspective view of an assembled portable imaging reader operative for electro-optically reading a target or symbol by image capture that can benefit from and use this invention;

FIG. 2 is a part-sectional, part-diagrammatic view of an imaging module in accordance with this invention for mounting in the reader of FIG. 1;

FIG. 3 is an enlarged, exploded, front perspective view of the imaging module of FIG. 2 in accordance with this invention;

FIG. 4 is an enlarged, exploded, front perspective view of the imaging module of FIG. 3 prior to its mounting in a shock mount in a housing of the reader of FIG. 1;

FIG. 5 is a view analogous to FIG. 4 after the imaging module of FIG. 3 has been mounted in the shock mount of FIG. 4;

FIG. 6 is an enlarged, rear perspective view after the imaging module of FIG. 3 has been mounted in the shock mount of FIG. 4; and

FIG. 7 is an enlarged, broken-away, front perspective view of the reader of FIG. 1 after the imaging module of FIG. 3 has been shock-mounted therein.

### DETAILED DESCRIPTION OF THE PREFERRED EMBODIMENTS

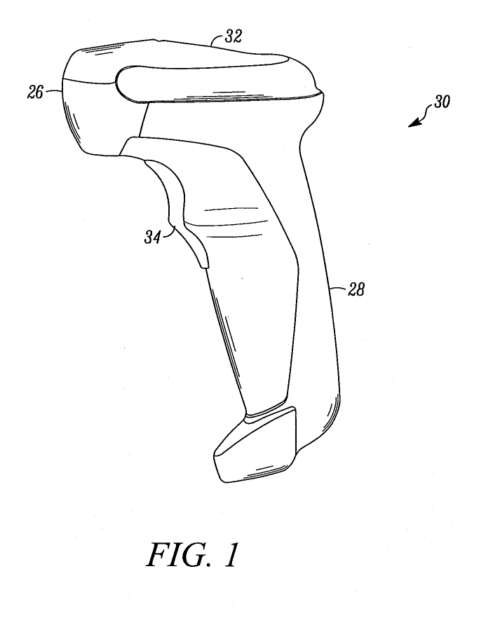

Reference numeral 30 in FIG. 1 generally identifies an ergonomic imaging reader configured as a gun-shaped housing having an upper housing part 32 and a lower housing part 28 that includes a handle tilted rearwardly away from the upper housing part 32 at an angle of inclination, for example, fifteen degrees, relative to the vertical. A window 40, as described in detail below, is located adjacent the front or nose 26 of the upper housing part 32. The imaging reader 30 is held in an operator's hand and used in a handheld mode in which a trigger 34 is manually depressed to initiate imaging of a target or symbol, especially one-dimensional symbols, to be read in a range of working distances relative to the window. Housings of other configurations can also be employed and operated in other modes, such as a hands-free mode of operation, by being supported on a countertop or like support surface.

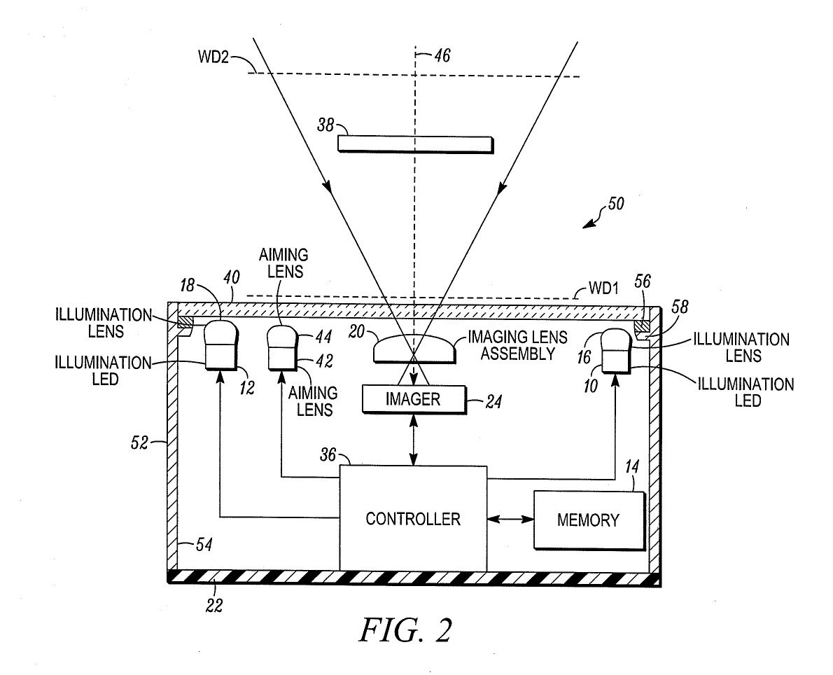

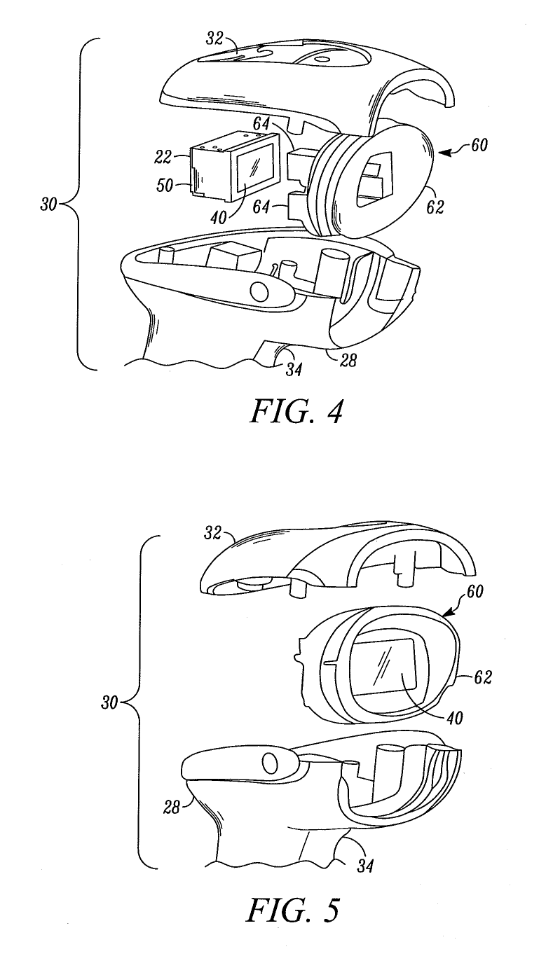

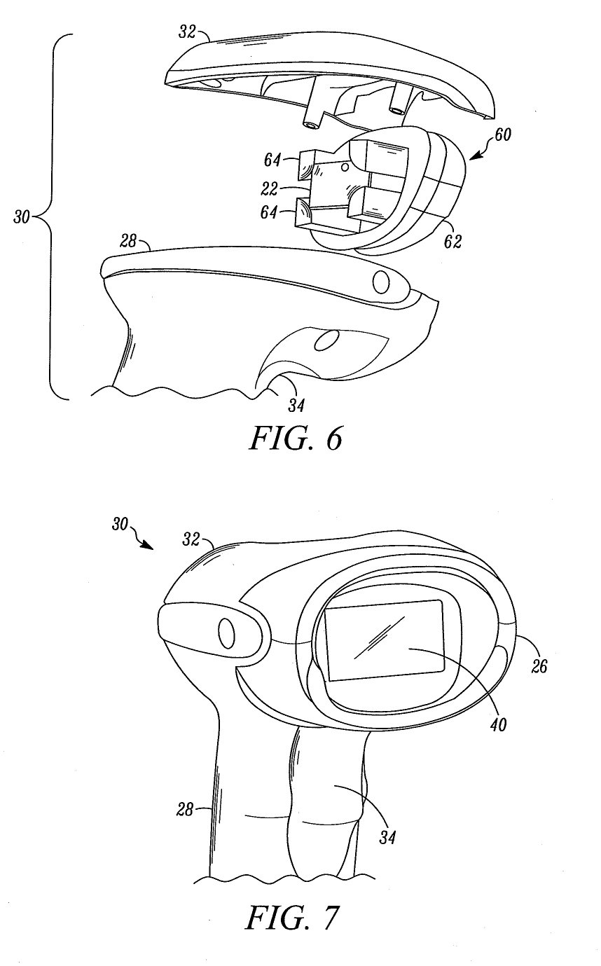

As schematically shown in isolation in FIG. 2, an imaging system or module 50 is mounted in the reader 30 in the manner depicted in FIGS. 4-7. The imaging module 50 includes a chassis having chassis walls 52 bounding an optical compartment 54, and a printed circuit board (PCB) 22 is mounted at the rear of the chassis. An image capture assembly is mounted in the optical compartment 54, and includes a solid-state imager 24, for example, a CCD or a CMOS device having a one- or two-dimensional array of addressable image sensors, operative for detecting return light captured by an imaging lens assembly 20 along an imaging axis 46 through the window 40 over a field of view, and for producing electrical signals corresponding to a one- or two-dimensional array of pixel data over the field of view. The return light is scattered and/or reflected from a target or symbol 38 over the field of view. The imaging lens assembly 20, e.g., a Cooke triplet, is also mounted in the optical compartment 54, and is operative for focusing the return light onto the array of image sensors to enable the symbol 38 to be read.

The symbol 38 may be located anywhere in a working range of distances between a close-in working distance (WD1) and a far-out working distance (WD2). In a preferred embodiment, WD1 is about one-half inch from the window 40, and WD2 is about thirty inches from the window 40. The imaging lens assembly 20 is preferably located in a close confronting relationship with the window 40, for example, no more than a few millimeters away.

An illuminating light assembly is also mounted in the optical compartment 54, and includes an illumination light source, e.g., at least one light emitting diode (LED), and preferably a plurality of LEDs, such as a pair of illumination LEDs 10, 12, and a pair of illumination lenses 16, 18 for shaping the illumination light emitted by the illumination LEDs 10, 12. At least part of the scattered and/or reflected return light is derived from the illumination pattern of light on and along the symbol 38. The illuminating light assembly is preferably located in a close confronting relationship with the window 40, for example, no more than a few millimeters away.

An aiming light assembly is also mounted in the optical compartment 54, and includes an aiming light source 42, e.g., a laser or at least one light emitting diode (LED), and an aiming lens 44 for shaping the aiming light emitted by the aiming LED 42. The aiming light assembly is also preferably located in a close confronting relationship with the window 40, for example, no more than a few millimeters away.

As shown in FIG. 2, the imager 24 and the LEDs 10, 12, 42 are operatively connected to a controller or programmed microprocessor 36 operative for controlling the operation of these components. A memory 14 is connected and accessible to the controller 36. Preferably, the microprocessor 36 is also used for processing the electrical signals from the imager 24 and for processing and decoding the captured target images. The controller 36 and the memory 14 need not be mounted inside the optical compartment 54, but advantageously are mounted on the PCB 22.

In operation, the microprocessor 36 sends command signals to initially energize the aiming LED 42 to project an aiming pattern on the target symbol 38, and then, to energize the illumination LEDs 10, 12 for a short exposure time period, say 500 microseconds or less, and to energize and expose the imager 24 to collect the return light, e.g., illumination light and/or ambient light, from the target symbol 38 only during said exposure time period. A typical array needs about 18-33 milliseconds to acquire the entire target image and operates at a frame rate of about 30-60 frames per second.

In accordance with one aspect of this invention, the window 40 for the reader 30 is not directly supported by the housing 28, 32, but instead, is supported by, and integrated with, the chassis walls 52 for joint movement with the chassis. As described above, the window 40 is positioned on the chassis, preferably in a close confronting relationship with the illuminating light assembly, to resist back reflections of the illumination light from the window 40 from entering the field of view of the image capture assembly. The window 40 is made of glass, plastic or like material transmissive to the illumination light, the aiming light and the ambient light. The window 40 may have a hard coating thereon to improve its scratch-resistant properties. In a preferred embodiment, the window 40 is a generally planar, rectangular pane of molded plastic. However, other shapes, such as cylindrical, spherical, aspherical, toroidal, and the like may be utilized. The window 40 may advantageously be formed with local curvatures or integral lenses for modifying the optical properties of the imaging lens assembly, the illuminating light assembly, or the aiming light assembly.

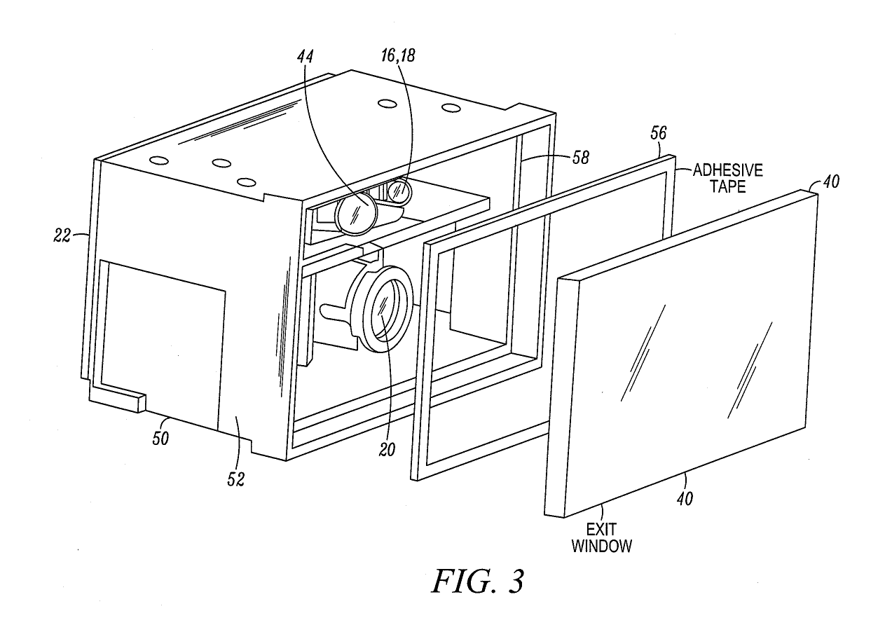

Preferably, as best shown in FIG. 3, a seal, such as a double-sided adhesive tape 56, is provided between the window 40 and the chassis walls 52 for sealing the optical compartment 54 from moisture, contaminants and stray light. The tape 56 is a rectangular frame that adheres to, and along, the rectangular periphery of the window 40. The chassis walls 52 include a rectangular, internal ledge 58 on which the tape 56 and the window 40 are seated.

Hence, by positioning the window 40 substantially perpendicular to the imaging axis 46 and as close as possible to the imaging lens assembly and to the illuminating light assembly, any back reflections off the window 40 are minimized, because any such back reflections do not enter the field of view of the imager 24.

As best seen in FIGS. 4-6, a shock mount 60 is operative for shock mounting the imaging module 50, together with its integrated window 40, in the housing 28, 32 to damp and resist any shock forces. The shock mount 60 is made of an elastomeric material, such as rubber, and has an annular front collar 62 that surrounds a front region of the chassis, and a plurality of rear projections 64 that grip and securely hold the imaging module 50 on all sides. The window 40 is thus protected from scratching, cracking and breakage when the reader is subjected to shock forces, because the window 40 does not move relative to the imaging module 50, but instead, jointly moves with the imaging module 50.

The imaging module 50 with its integrated window 40 can be easily installed in original equipment manufacturer (OEM) product applications. Product integrators of the imaging module 50 do not need to be concerned with correctly locating the exit window 40 in the final product, since the window 40 is already provided with the imaging module 50. The imaging module 50 with its integrated window 40 comprise an air/moisture sealed unit and, by this means, further facilitates its easy integration of the sealed unit in OEM products.

It will be understood that each of the elements described above, or two or more together, also may find a useful application in other types of constructions differing from the types described above.

While the invention has been illustrated and described as a shock-mounted imaging module with an integrated window for, and a method of, resisting and avoiding back reflections in an imaging reader, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

What is claimed as new and desired to be protected by Letters Patent is set forth in the appended claims.

We claim:

1. An imaging module for an imaging reader operative for electro-optically reading a target by image capture, comprising:
a chassis having chassis walls bounding an optical compartment;
an illuminating light assembly in the optical compartment for illuminating the target with illumination light for return from the target;
an image capture assembly in the optical compartment for capturing return light from the target over a field of view; and
a light-transmissive window for the reader, the window being supported by, and integrated with, the chassis walls for joint movement with the chassis, the window being positioned relative to the illuminating light assembly to resist back reflections of the illumination light from the window from entering the field of view of the image capture assembly.

2. The imaging module of claim 1, wherein the illuminating light assembly includes at least one illuminating light source for emitting the illumination light, and an illuminating lens for directing the emitted illumination light through the window for reflection and scattering from the target; and wherein the window is positioned in a close confronting relationship with the illuminating light assembly.

3. The imaging module of claim 1, wherein the image capture assembly includes a solid-state imager and an imaging lens for capturing the return light along an imaging axis through the window, and for projecting the return light onto the imager to initiate capture of an image of the target.

4. The imaging module of claim 1, and a seal between the window and the chassis walls for sealing the optical compartment.

5. An imaging reader for electro-optically reading a target by image capture, comprising:
a housing;
an imaging module including
a chassis having chassis walls bounding an optical compartment,
an illuminating light assembly in the optical compartment for illuminating the target with illumination light for return from the target,
an image capture assembly in the optical compartment for capturing return light from the target over a field of view, and
a light-transmissive window for the housing, the window being supported by, and integrated with, the chassis walls for joint movement with the chassis, the window being positioned relative to the illuminating light assembly to resist back reflections of the illumination light from the window from entering the field of view of the image capture assembly; and
a shock mount for mounting the imaging module in the housing to damp shock forces.

6. The reader of claim 5, wherein the illuminating light assembly includes at least one illuminating light source for emitting the illumination light, and an illuminating lens for directing the emitted illumination light through the window for reflection and scattering from the target; and wherein the window is positioned in a close confronting relationship with the illuminating light assembly.

7. The reader of claim 5, wherein the image capture assembly includes a solid-state imager and an imaging lens for capturing the return light along an imaging axis through the window, and for projecting the return light onto the imager to initiate capture of an image of the target.

8. The reader of claim 5, and a seal between the window and the chassis walls for sealing the optical compartment.

9. The reader of claim 5, wherein the shock mount is a collar that at least partly surrounds the imaging module.

10. The reader of claim 9, wherein the housing has a pair of housing portions bounding an interior, and sandwiching the collar between the housing portions in the interior of the housing.

11. The reader of claim 6, wherein the image capture assembly captures the return light along an imaging axis, and wherein the window lies in a plane that is substantially perpendicular to the imaging axis.

12. A method of avoiding back reflections of illumination light from a window from entering a field of view of an image capture assembly in an imaging reader for capturing return light from a target to be electro-optically read, the method comprising the steps of:
supporting the window by a chassis for joint movement with the chassis to form an integrated imaging module; and
positioning the window relative to an illuminating light assembly that illuminates the target through the window with the illumination light to resist the back reflections from entering the field of view of the image capture assembly.

13. The method of claim 12, wherein the target is illuminated by emitting and directing the illumination light through the window for reflection and scattering from the target; and wherein the positioning step is performed by positioning the window in a close confronting relationship with the illuminating light assembly.

14. The method of claim 12, wherein the return light is captured along an imaging axis through the window, and configuring the window to lie in a plane that is substantially perpendicular to the imaging axis.

15. The method of claim 12, and mounting the image capture assembly and the illuminating light assembly in an optical compartment of the chassis, and sealing the optical compartment.

16. The method of claim 12, and shock mounting the integrated imaging module in the reader to damp shock forces.

17. The method of claim 16, wherein the shock mounting step is performed by a collar that at least partly surrounds the integrated imaging module.

18. The method of claim 17, and configuring the reader with a pair of housing portions bounding an interior, and sandwiching the collar between the housing portions in the interior of the housing.
